(19) United States
(12) Patent Application Publication
(10) Pub. No.: US 2011/0248724 A1
(43) Pub. Date: Oct. 13, 2011

(54) DETECTION ELEMENT FOR DETECTING AN ELECTROMAGNETIC WAVE

(75) Inventor: Ryota Sekiguchi, Kawasaki-shi (JP)

(73) Assignee: CANON KABUSHIKI KAISHA, Tokyo (JP)

(21) Appl. No.: 13/071,222

(22) Filed: Mar. 24, 2011

(30) Foreign Application Priority Data
Apr. 12, 2010 (JP) 2010-091682

(51) Int. Cl. G01R 27/04

(52) U.S. Cl. 324/633; 324/629

(57) ABSTRACT

A detection element for detecting an electromagnetic wave includes: a substrate; a schottky barrier diode disposed on the substrate; and an antenna disposed on the substrate, wherein the antenna includes a first conductive element and a second conductive element which are divided, a third conductive element and a fourth conductive element which are divided, a first connecting member that electrically connects the first conductive element and the third conductive element, and a second connecting member that electrically connects the second conductive element and the fourth conductive element, wherein the first conductive element and the second conductive element, and the third conductive element and the fourth conductive element are formed on multiple surfaces of the substrate, which are spaced apart from each other along an incident direction of the electromagnetic wave, respectively, and wherein the schottky barrier diode is electrically connected between the first conductive element and the second conductive element.

### BACKGROUND OF THE INVENTION

1. Field of the Invention

The present invention relates to an electromagnetic wave detection element using a rectifier element, and more particularly, to an electromagnetic wave detection element in a frequency band within a frequency range from a millimeter waveband to a terahertz band (a range of from 30 GHz to 30 THz, hereinafter used in the same sense), and a device using the electromagnetic wave detection element.

2. Description of the Related Art

As the electromagnetic wave detection element from a millimeter waveband to a terahertz band, a thermal detection element and a quantum detection element have been known up to now. The thermal detection element includes a microbolometer (a-Si, VOx, etc.), a pyroelectric element (LiTaO₃, TGS, etc.), a Golay cell, and the like. Such a thermal detection element converts a physical change caused by an energy of an electromagnetic wave into heat, and converts a temperature change into a thermoelectromotive force or a resistance for detection. Cooling is not always required, but a response is relatively slow because heat exchange is used. The quantum detection element includes an intrinsic semiconductor element (MCT (HgCdTe) photoconductive element, etc.), an impurity semiconductor device, and the like. This quantum detection element captures the electromagnetic wave as photons, and detects a photovoltaic power or resistance change of semiconductor having a small band gap. The response is relatively fast, but cooling is required because a thermal energy of a room temperature in such a frequency range cannot be ignored.

Under the circumstances, recently, as the detection element having relatively fast response and requiring no cooling, the electromagnetic wave detection element using the rectifier element from the millimeter waveband to the terahertz band has been developed. The detection element captures the electromagnetic wave as a high-frequency electric signal, rectifies the high-frequency electric signal, which has been received through an antenna, by the rectifier element, and detects the electromagnetic wave. The detection element of this type is disclosed in Japanese Patent Application Laid-Open No. H09-162424. As disclosed in H. Kazemi et al, Proc. SPIE Vo. 6542, 65421J (2007), a planar antenna such as a spiral antenna has been known as the receive antenna. The planar antenna receives the electromagnetic wave of 2.5 THz or 28.3 THz.

However, in the conventional detection element using a schottky barrier diode, an element resistance of the schottky barrier diode is larger than an impedance of the planar antenna. This is because, in order to support the frequency range from the millimeter waveband to the terahertz band, the miniaturization of the element structure is required, and a current that can flow through the element is limited. For that reason, impedance mismatch to the conventional planar antenna with a small impedance has been a problem.

### SUMMARY OF THE INVENTION

A detection element for detecting an electromagnetic wave according to the present invention includes: a substrate; a schottky barrier diode disposed on the substrate; and an antenna disposed on the substrate, wherein the antenna includes a first conductive element and a second conductive element which are divided, a third conductive element and a fourth conductive element which are divided, a first connecting member that electrically connects the first conductive element and the third conductive element, and a second connecting member that electrically connects the second conductive element and the fourth conductive element, wherein the first conductive element and the second conductive element, and the third conductive element and the fourth conductive element are formed on multiple surfaces of the substrate, which are spaced apart from each other along an incident direction of the electromagnetic wave, respectively, and wherein the schottky barrier diode is electrically connected between the first conductive element and the second conductive element.

According to the electromagnetic wave detection element of the present invention, the antenna is formed across multiple surfaces located at different level positions along the incident direction of the electromagnetic wave. Therefore, the antenna may have a larger impedance than that of the planar antenna in the conventional detection element, and the impedance mismatch to the schottky barrier diode element may be reduced.

Further features of the present invention will become apparent from the following description of exemplary embodiments with reference to the attached drawings.

### BRIEF DESCRIPTION OF THE DRAWINGS

FIG. 1A is a cross-sectional view illustrating a configuration of a detection element according to a first embodiment of the present invention.

FIG. 1B is a perspective view illustrating the configuration of the detection element according to the first embodiment of the present invention.

FIG. 2A is a graph showing a current distribution of a detected electromagnetic wave in a detection element according to a second embodiment.

FIG. 2B is a cross-sectional view illustrating a configuration of the detection element according to the second embodiment.

FIG. 3 is a cross-sectional view illustrating a configuration of a detection element according to a third embodiment.

FIG. 4 is a cross-sectional view illustrating a configuration of a detection element according to a fourth embodiment.

FIG. 5A is a cross-sectional view illustrating a configuration of a detection element according to Example 1 of the present invention.

FIG. 5B is a bird's-eye view illustrating an analysis model of the detection element according to Example 1 of the present invention.

FIG. 5C is a graph showing simulation results of the detection element according to Example 1 of the present invention.

FIG. 6A is a cross-sectional view illustrating a configuration of a detection element according to Example 2.

FIG. 6B is a bird's-eye view illustrating an analysis model of the detection element according to Example 2.

FIG. 6C is a graph showing simulation results of the detection element according to Example 2.

FIG. 7 is a graph showing simulation results of a detection element according to a modified example of Example 1.

### DESCRIPTION OF THE EMBODIMENTS

An electromagnetic wave detection element according to the present invention has a feature in that an antenna is formed across multiple surfaces located at different level positions, which are spaced apart from each other along an incident direction of an electromagnetic wave.

An idea of the electromagnetic wave detection element according to the present invention is further described. In the conventional detection element that detects the electromagnetic wave received through an antenna by using a rectifier element for rectifying a high-frequency electric signal which is generated by the electromagnetic wave, the rectifier element is a schottky barrier diode. In such a configuration, for example, a schottky electrode is microfabricated to have an area of 0.0007 μm² (0.03 μm in diameter) so as to detect the electromagnetic wave of about 28 THz (10.6 μm in wavelength) generated by CO₂ laser. The schottky barrier diode involves an RC low-pass filter formed of a junction capacitor Cⱼ and a series resistor Rₛ, in the schottky barrier. Because the junction capacitor Cⱼ is proportional to the area of the schottky electrode, the simplest method for increasing a cutoff frequency f_{c} (=(2π×RₛCⱼ)⁻¹) so as to detect the high-frequency electromagnetic wave is to reduce the area of the schottky electrode. When simply calculating a relationship between the area of the schottky electrode and the cutoff frequency of the typical schottky barrier diode, if the schottky electrode is microfabricated to have the area of 1 μm² (about 1 μm in terms of diameter), f_{c} takes about 300 GHz. If the schottky electrode is microfabricated to have the area of 0.1 μm², which is 1/10 of 1 μm² (about 0.3 μm in terms of diameter), f_{c} takes about 3 THz. Further, if the schottky electrode is microfabricated to have the area of 0.01 μm², which is 1/10 of 0.1 μm² (about 0.1 μm in terms of diameter), it is estimated that f_{c} takes about 30 THz. When the electromagnetic wave of this frequency is to be detected, the element resistance of the schottky barrier diode becomes about 1,000Ω or more at a rough estimate. For that reason, impedance mismatch occurs in the planar antenna with a small impedance, and hence in the present invention, a dipole antenna is formed across multiple surfaces located at different level positions on a substrate so as to increase an impedance thereof.

Typically, as described in embodiments and examples below, multiple conductive elements of the antenna are arranged so that the conductive elements substantially overlap with each other so as to be spaced apart from each other along an incident direction of the electromagnetic wave through a dielectric layer, when viewed from the incident direction. Other separation may be used alternatively. For example, the substrate is recessed to form a bottom surface of the recess and a top surface around the recess, and first and second conductive elements are arranged on the bottom surface of the recess, whereas third and fourth conductive elements are arranged on the top surface so as to be slightly displaced in parallel to those first and second conductive elements. In this case, the recess can be filled with a dielectric layer, the first and third conductive elements can be electrically connected to each other through a connecting member in the dielectric layer, and the second and fourth conductive elements can be electrically connected to each other through another connecting member in the dielectric layer. The third and fourth conductive elements may be substantially completely formed on the top surface, or may be slightly extended out to the recess side.

Further, as described in the embodiments and examples below, the respective conductive elements of the antenna may be constituted by stripe elements. Instead, for example, the respective conductive elements can be of a triangular configuration (for example, isosceles triangular configuration), in which the vertexes of the respective triangles face each other with a gap. In the case of such a bow-tie antenna, each of the paired triangular elements is arranged on multiple surfaces spaced apart from each other in the incident direction of the electromagnetic wave.

The length of the perpendicular line of each triangle is set to λ/4, the length of the oblique line thereof is set to λ′/4 (λ≠λ′), and upper and lower triangular elements are connected by a connecting member on the side of the base of the triangle. According to this configuration, the electromagnetic wave of the wavelength λ or λ′ including a polarized wave component in a direction of the perpendicular line or the oblique line can be detected. Further, the stripe conductive element may be replaced with an antenna including conductive elements having a shape of bent stripe. In this case, one ends of bent shapes may face each other with a gap, and upper and lower bent conductive elements may be connected by a connecting member at the other end. In this spiral antenna, the electromagnetic waves including polarized wave components in different directions (such as circularly polarized light), and the electromagnetic waves having different wavelengths can be detected.

Hereinafter, embodiments and examples of the present invention are described with reference to the accompanying drawings.

### First Embodiment

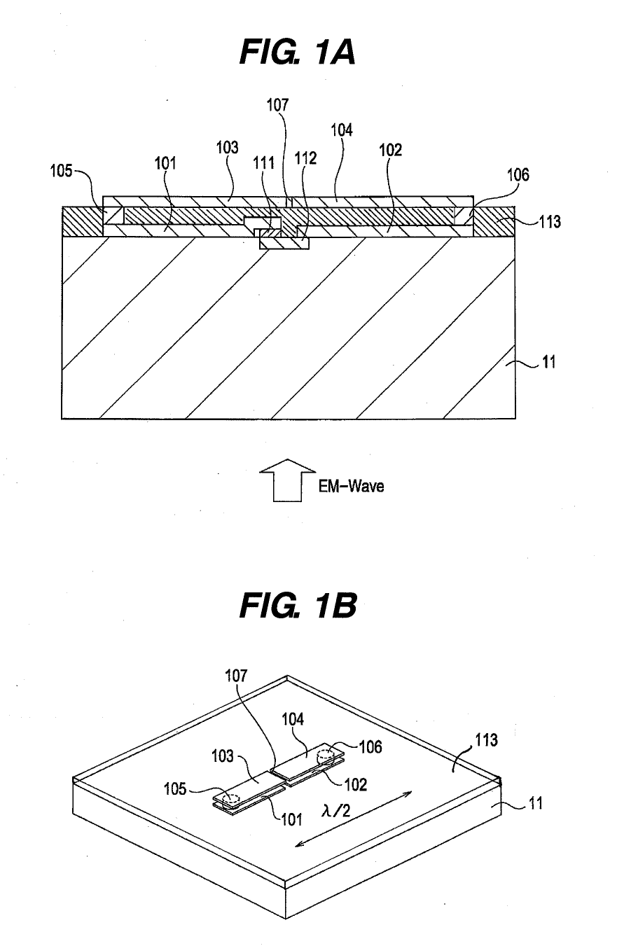

A detection element according to a first embodiment of the present invention is described with reference to FIGS. 1A and 1B. FIG. 1A is a cross-sectional view illustrating the detection element according to this embodiment, and FIG. 1B is a perspective view thereof.

The detection element according to this embodiment includes four conductive elements constituting an antenna, and two vias that are connecting members. Each of a divided first conductive element 101 and a divided second conductive element 102 is formed of a stripe metal film whose length is ¼ of a wavelength of the electromagnetic wave (λ/4). The elements 101 and 102 constitute a λ/2 dipole antenna, and a length direction thereof is a resonant direction of the electromagnetic wave. λ is a wavelength of the electromagnetic wave to be detected, which is not in a vacuum but is an effective wavelength multiplied by a wavelength compression ratio depending on a substrate 11. The elements 101 and 102 come into contact with a low carrier concentration semiconductor 111 and a high carrier concentration semiconductor 112 on the nonconductive substrate 11, respectively. The elements 101 and 102 are made of a schottky metal and an ohmic metal, respectively. The schottky barrier diode is made up of the element 101 as the schottky metal, the low carrier concentration semiconductor 111, the high carrier concentration semiconductor 112, and the element 102 as the ohmic metal. Hence, the elements 101 and 102 form the λ/2 dipole antenna, and also serve as an electrode of the schottky barrier diode element.

A divided third conductive element 103 and a divided fourth conductive element 104 are arranged in another layer immediately above the elements 101 and 102. In this way, the antenna is formed across multiple surfaces located at different positions along an incident direction of the electromagnetic wave. The element 103 is connected to the element 101 through a first via 105 that is a first connecting member disposed in a dielectric material 113. Likewise, the element 104 is connected to the element 102 through a second via 106 that is a second connecting member disposed in the dielectric material 113. Because the vias 105 and 106 are located at ends of the elements 101 and 102 as the dipole antennas, the above-mentioned four elements constitute pseudo folded dipole antennas where the dipole antennas are folded. In this example, the configuration of the vias 105 and 106 are cylindrical, but the configuration and a cross-sectional area of the vias 105 and 106 are freely designed so far as electric connection is enabled. It is usually known that all elements of the folded dipole antennas are short-circuited. However, in this embodiment, with the provision of a DC cut 107, the elements 103 and 104 physically have no contact with each other. This is to extract a detection signal from the schottky barrier diodes (101, 111, 112, 102). Accordingly, the detection signal indicative of whether the electromagnetic wave is detected or not can be extracted from the elements 101 and 102 as the electrodes as a voltage or a current.

The schottky barrier diode has a current-voltage characteristic in which a current flows at a forward voltage, and no current flows at a backward voltage. At a turning point thereof, a current density J is proportional to an exponential function Exp (eV/kT), where V is a voltage, e is an elementary charge, k is Boltzmann constant, and T is an absolute temperature. A proportionality coefficient J₀ is A⁺T²×Exp(−φ_{B}/kT) based on thermoionic-field-emission, where A⁺ is effective Richardson constant, and for example, a constant of about 10 A/cm²K for typical semiconductor. When the temperature is fixed, J₀ is determined by only a schottky barrier height φ_{B} which is an interface potential between the element 101 as the schottky electrode and the semiconductor 111. The schottky barrier height φ_{B} is typically several hundreds meV. Assuming that (PB is, for example, 200 meV, the proportionality coefficient J₀ is about 400 A/cm² at room temperature. In order to support the frequency range from the millimeter waveband to the terahertz band, a contact area S between the element 101 as the schottky metal and the semiconductor 111 needs to be miniaturized. In terms of the element structure of 1 μm² or lower, I₀ (=S×J₀ becomes 4 μA or lower. The resistance value of the element obtained by differentiating an inverse number of a current I (=S×J) with respect to V is equal to kT/(e×I₀)×Exp(−eV/kT). The resistance value becomes 6,000Ω or higher at an operating point voltage V=0 mV at room temperature, and becomes 130Ω or higher even at a relatively high operating point voltage V=100 mV in a range having a detection sensitivity. Accordingly, the element resistance of the schottky barrier diodes (101, 111, 112, 102) becomes about 1,000Ω or higher at a rough estimate as described above.

On the other hand, it has been theoretically known that the impedance of the folded dipole antenna is four times 73Ω, which is the impedance of the λ/2 dipole antenna. That is, the impedance is about 300Ω. This value is larger than 188Ω (typically 50Ω to 100Ω), which is the theoretical impedance of a self complementary antenna such as a spiral antenna, a bow-tie antenna, or a log periodic antenna. Accordingly, it is preferred to use the folded dipole antenna from the viewpoint of the above-mentioned impedance match to the schottky barrier diode element. When the impedance is matched, reflection from the schottky barrier diode element becomes zero, and hence the power efficiency is obtained by 1− [symbol] using the reflection coefficient [symbol] =(Rₐ−R_{d})/(Rₐ+R_{d}). In this expression, Rₐ is an impedance at a resonance point of the antenna, and R_{d} is an element resistance of the schottky barrier diode. When it is assumed that the element resistance of the schottky barrier diode is 1,000Ω, the power efficiency becomes 70% in the case of using the folded dipole antenna. Referring to the other antennas, the power efficiency in the self complementary antenna of the impedance 188Ω is 53%, and the power efficiency in the λ/2 dipole antenna of the impedance 73Ω is 25%. In fact, because of the dielectric constant of the substrate 11, all of those antennas are small in impedance. Notwithstanding, it is preferred to use the folded dipole antenna.

Because of the dielectric constant ∈ᵣ (>1) of the substrate 11 which is higher than that of air, the directivity of the folded dipole antenna according to this embodiment is slanted toward a direction of the substrate 11 side. Accordingly, as illustrated in FIG. 1A, the electromagnetic wave to be detected is input from a rear surface of the substrate. In this situation, a dielectric lens may be disposed on the rear surface of the substrate 11 so as to prevent total reflection from the rear surface of the substrate 11 and enhance the directivity. The wavelength of the electromagnetic wave to be detected is selected by the λ/2 dipole antenna constituted by the elements 101 and 102. As described above, λ is an effective wavelength multiplied by a wavelength compression ratio depending on the substrate 11. In this way, the elements 103 and 104, and the vias 105 and 106 have the effect of quadruplicating the impedance of the antenna so as to reduce the impedance mismatch. Hence, the sensitivity of the detection element can be increased.

The details of the other detecting operations are the same as those in the above-mentioned prior art document. That is, a structure is made in which majority carrier cannot pass through the energy barrier of the barrier of the schottky barrier diode without application of an electric field in a certain direction. That is, in the electric field in the certain direction, the majority carrier is subjected to thermoionic-field-emission by the energy barrier, and in an electric field in the reverse direction, the majority carrier cannot tunnel the energy. This mechanism occurs when the majority carrier is sufficiently reduced in the semiconductor on one side, which constitutes the energy barrier. In the element of this embodiment, only when the electric field is applied in the certain direction (electric field developed by the incident electromagnetic wave) (called “forward voltage”), a band profile in which the same majority carrier passes through the schottky barrier is formed. In the reverse electric field (similarly, electric field developed by the incident electromagnetic wave), no current flows. In the element thus constituted according to this embodiment, when an electric field component of the electromagnetic wave to be detected is induced between the element 101 as the schottky electrode and the element 102 as the ohmic electrode, a current flows in one direction based on the above-mentioned mechanism. This current includes a vibration component of the vibration frequency equal to the frequency of the electromagnetic wave to be detected. However, because the effective value of the current is not zero, the current becomes a detected current. Accordingly, the configuration of the element according to this embodiment is positioned as a so-called rectifier element, and becomes the detection element having a system using rectification.

It is assumed that the metal film element according to this embodiment is several hundreds nm in thickness and several μm in width. The width of the metal film element is wide taking into account a skin depth of the metal film supporting the frequency range from the millimeter waveband to the terahertz band. However, this influence does not change the magnitude of the impedance, but merely slightly shifts the resonance point. As illustrated in FIG. 1B, the antenna is inductive when a thickness of the dielectric material 113 that separates the element 101 and the element 103 (likewise, a thickness of the dielectric material 113 that separates the element 102 and the element 104) is thin, and is capacitive when the thickness is thick. For that reason, a height of the via 105 (likewise, the via 106) only needs to be maintained to several μm which is the same degree as the width of the metal films. Further, all of the widths of the metal film elements may not be identical with each other. When the width of the elements 103 and 104 is designed to be slightly broader than that of the elements 101 and 102, the impedance of the antenna becomes large. On the contrary, when the former is designed to be slightly narrower than the latter, the impedance of the antenna becomes small. In any case, because the above-mentioned dimensions can be created with the aid of the semiconductor process technology, it is preferred that the folded dipole antenna according to this embodiment be a planar antenna on the substrate.

### Second Embodiment

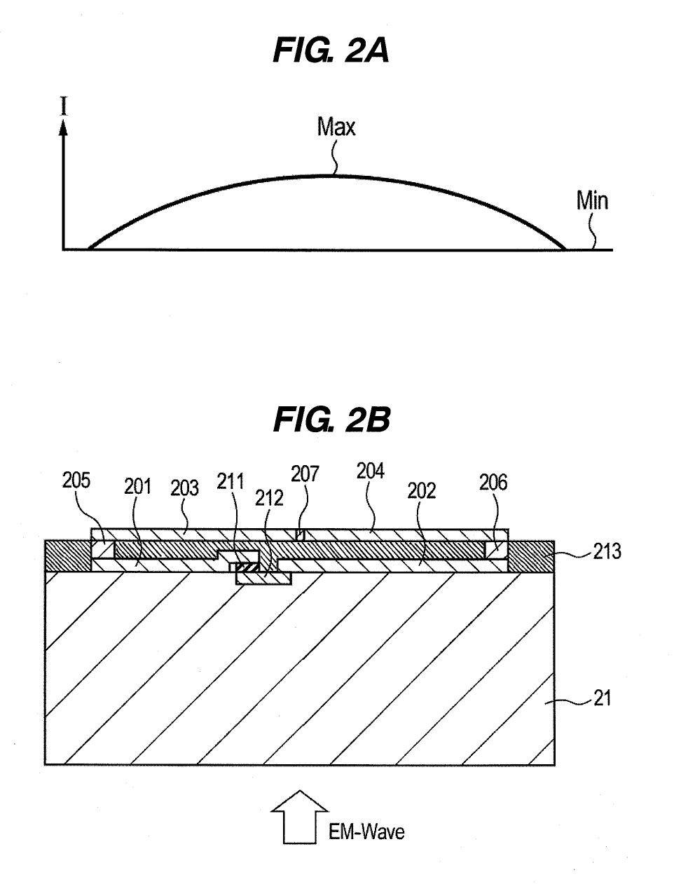

A detection element according to a second embodiment is described with reference to FIGS. 2A and 2B. In this embodiment, as illustrated in FIG. 2B, lengths of elements 201 and 202 and positions of semiconductors 211 and 212 are different from those in the first embodiment. The others are identical with those in the first embodiment. That is, elements 203 and 204, vias 205 and 206, a DC cut 207, and a dielectric material 213 are identical with those in the first embodiment. A sum of the lengths of the elements 201 and 202 is λ/2, and the elements 201 and 202 are still λ/2 dipole antenna. This embodiment is a modified example of the first embodiment in which positions of the schottky barrier diodes 201, 211, 212, and 202 are offset for increasing the input impedance of the antenna.

As shown in FIG. 2A, a current distribution I of the detected electromagnetic wave on the elements 201 and 202, and the elements 203 and 204 is minimum at positions corresponding to edges of the dipole antenna 201 and 202 along the resonance direction of the electromagnetic wave, and is maximum just at a center position between those edges. In this case, because the input impedance of the antenna is inversely proportional to the current I, when the positions of the semiconductors 211 and 212 are offset from the center, the input impedance of the antenna can be increased. However, when the positions of the semiconductors 211 and 212 are too offset from the center, the resonance point at which an imaginary part of the impedance becomes zero is not generated. For that reason, as a result of check using an electromagnetic field simulation through a simplified moment method, it is desired that the offset be within λ/8 from the center. From the viewpoint of the lengths of the first conductive element 201 and the second conductive element 202, it is desired that each of those lengths range from ⅛ to ⅜ of the wavelength of the electromagnetic wave along the resonance direction of the electromagnetic wave to constitute the dipole antenna. In this case, the input impedance changes from about 300Ω (no offset) to about 450Ω (offset of λ/8). In fact, because of the dielectric constant of a substrate 21, the impedance becomes small. Notwithstanding, the input impedance of the antenna is larger in the case of using the offset, which is preferred.

### Third Embodiment

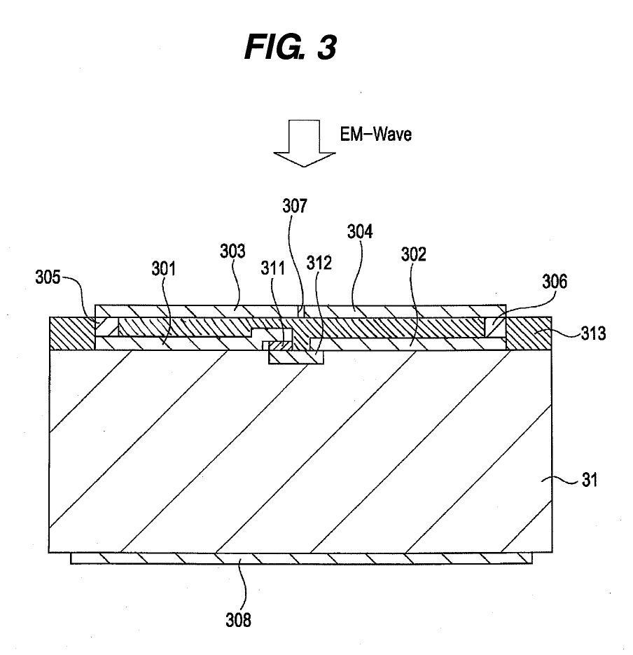

A detection element according to a third embodiment is described with reference to FIG. 3. The detection element according to this embodiment includes four elements and two vias which constitute an antenna, and a metal film element 308 which is an additional fifth conductive element. In this embodiment, elements 301, 302, 303, and 304, vias 305 and 306, a DC cut 307, semiconductors 311 and 312, and a dielectric material 313 are identical with those in the first embodiment. The additional element 308 is located on a rear surface of a substrate 31 which is a surface opposite to the surface of the substrate on which the antenna is disposed, and a length thereof is set to be slightly longer than λ/2. This embodiment shows an example in which the directivity of the antenna in the first embodiment is changed to a surface direction of the substrate 31 (upward in FIG. 3).

The element 308 slightly longer than λ/2 derives from a technique called “reflector” that has been known by Yagi antennas, and the directivity of the folded dipole antenna is slanted to a surface direction of the substrate (air side). For that reason, it is preferred that a thickness of the substrate 31 be adjusted to about λ/4. Advantageously, the thickness of the substrate 31 corresponding to λ/4 of the frequency range from the millimeter waveband to the terahertz band can be easily achieved by polishing the substrate and putting another substrate on the substrate. Further, in order to expand the effects of the reflector, a metal film element slightly longer than λ/2 may be added to another substrate having the same thickness of λ/4, and put on the rear surface of the substrate 31. On the contrary, the length of the additional element 308 is set to be slightly shorter than λ/2 to provide a wave director. In this situation, the directivity of the folded dipole antenna is further slanted to a direction of the substrate 31 side (downward in FIG. 3), and an antenna gain and a directivity increase, which is preferred. In this case, the electromagnetic wave is input from the rear surface side of the substrate 31.

### Fourth Embodiment

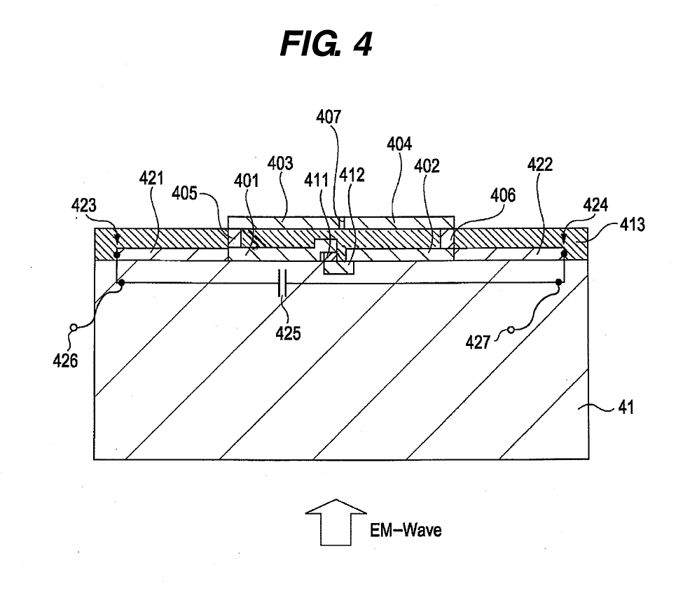

A detection element according to a fourth embodiment is described with reference to FIG. 4. The detection element according to this embodiment includes four elements and two vias which constitute an antenna, a first stub 421, a second stub 422, a capacitor 425, and read lines 426 and 427. In this embodiment, elements 401, 402, 403, and 404, vias 405 and 406, a DC cut 407, semiconductors 411 and 412, and a dielectric material 413 are identical with those in the first embodiment. The element 401 and the element 402, and the element 403 and the element 404 are λ/2 in length, respectively. This embodiment shows an example in which the detection signal is read so as not to affect the detected electromagnetic wave.

Portions 421 and 422 extending from the metal film elements 401 and 402 are capacitively coupled at positions 423 and 424 where extension lengths become λ/4, respectively. Therefore, a metal film constituting the short stubs 421 and 422 each having a length of λ/4 is formed. A current distribution of the detected electromagnetic wave in the short stubs 421 and 422 is large at the positions 423 and 424, and is small at positions corresponding to the respective connecting members of the stubs 421 and 422, and the dipole antennas 401 and 402. Hence, the stubs 421 and 422 do not affect the function of the antenna. Because several hundreds fF suffices for the capacitor 425 for capacitive coupling, the capacitor 425 may be formed by provision of a metal/insulator/metal (MIM) structure on the same substrate 41, for example. This configuration is preferred because the detection signal can be read so as not to affect the detected electromagnetic wave. For example, the read lines 426 and 427 may be connected between two terminals of the capacitor 425. For example, the MIM structure is disposed on the surface of the substrate 41, and wirings from the outer ends of the stubs 421 and 422 are arranged on the surface of the substrate 41 and connected to terminals of the MIM structure. Needless to say, such reading of the detection signal is one example.

More specific detection elements are described in the following examples.

### Example 1

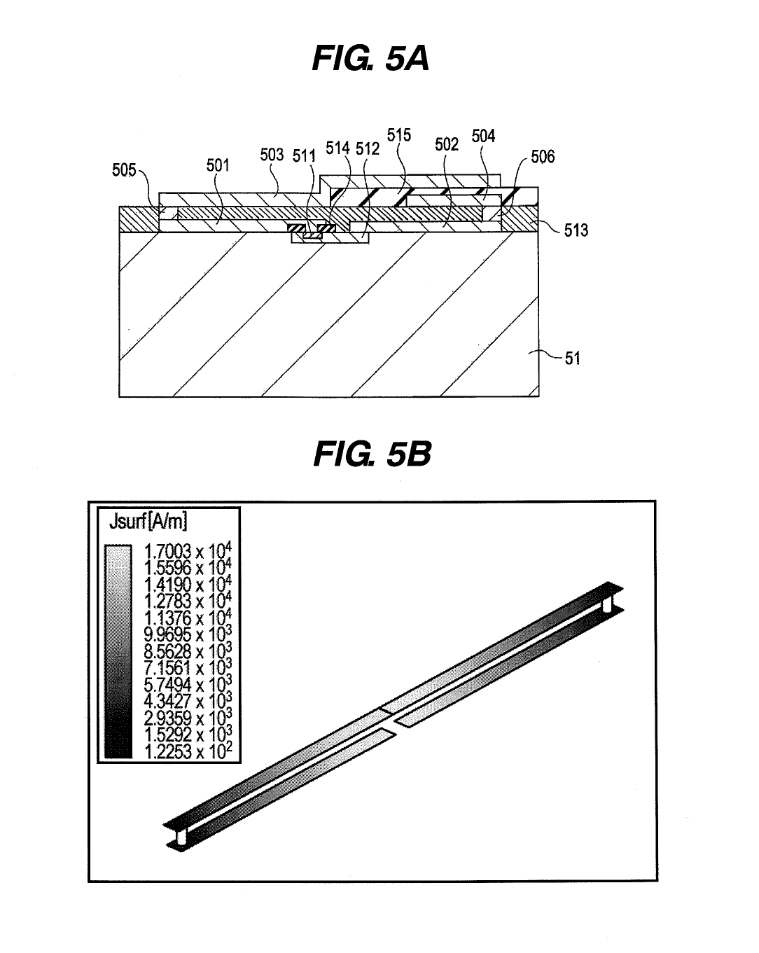

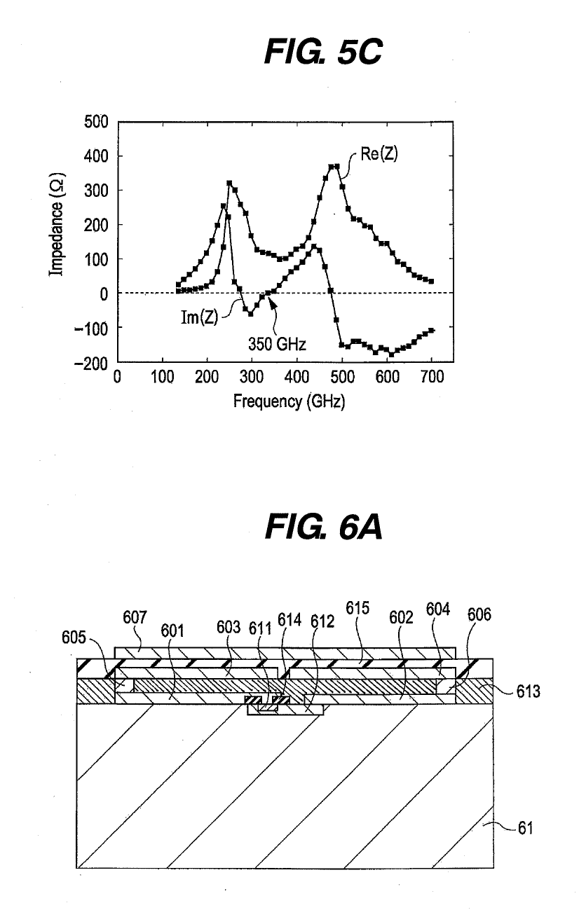

A detection element according to Example 1 is described with reference to FIGS. 5A to 5C. FIG. 5A is a cross-sectional view illustrating the detection element according to this example, FIG. 5B is a bird's-eye view illustrating an analysis model used for total electromagnetic field simulation, and FIG. 5C is a graph showing a frequency dependency of the impedance. In the total electromagnetic field simulation, commercial HFSS ver 11.2 made by Ansoft Corporation, which is known as a three-dimensional finite element method solver, is used.

The detection element according to this example is formed on an Fz-Si substrate 51. Referring to FIG. 5A, antenna elements 501, 502, 503, and 504 are made of Al metal which is 4 μm in width and 350 nm in thickness. In this example, a detection element that receives a terahertz wave having a frequency of 350 GHz is exemplified, and respective lengths of the element 501 and the element 502 are designed to 80 μm. The effective wavelength λ on the substrate 51 of a dielectric constant ∈ᵣ can be roughly estimated by λ₀/√∈_{eff} (∈_{eff}=(∈ᵣ+1)/2) obtained by multiplying a wavelength λ₀ in a vacuum by a wavelength compression ratio of an effective dielectric constant ∈_{eff}. The elements 503 and 504 are located in a layer immediately above the elements 501 and 502. Those elements are spaced from each other by 5 μm in the thickness direction (incident direction of the electromagnetic wave). A dielectric material 513 is made of low-loss benzocyclobutene (BCB). The element 503 is connected to the element 501 through a via 505 disposed in the BCB 513. Likewise, the element 504 is connected to the element 502 through a via 506 disposed in the dielectric material 513. In FIG. 5B, a positional relationship of those elements can be visually understood.

In this example, DC cut is realized by deforming the elements 503 and 504. That is, a part of the element 503 is put immediately above the element 504 insulated by a protective film 515 to realize the DC cut and AC short-circuit. Accordingly, it is preferred that the protective film 515 be thinner, and hence the protective film 515 is made of SiO₂ that is 200 nm in thickness in this example. In this example, a length of the element 503 is 160 μm (λ/2), and a length of the element 504 is 40 μm. In the above-mentioned respective antenna elements of the folded dipole antenna according to this example, FIG. 5B shows a surface current distribution of the received electromagnetic wave. As described in the second embodiment, a larger portion of the surface current distribution is around the center, and the distribution is smaller at the portions of the vias 505 and 506. Further, FIG. 5C shows the impedance of the folded dipole antenna according to this example. According to the total electromagnetic field simulation, the impedance of the antenna becomes about 120Ω in the vicinity of the resonance point (a point where an imaginary part Im(Z) becomes zero, and 350 GHz) of the antenna. When an influence (∈_{eff}=(∈ᵣ+1)/2) of the substrate 51 is removed, the impedance is estimated as about 300Ω. Therefore, it is understood that this is correctly designed. This value is a relatively large impedance even taking the other planar antenna on the same substrate into consideration.

Schottky barrier diodes 501, 511, 512, and 502 ensure an n type region 511 and an n⁺ type region 512 formed by ion implantation. The schottky barrier occurs between the Al metal 501 and the n-type region 511. Because tunneling emission is dominant rather than thermoionic-field-emission between the Al metal 502 and the n⁺ type region 512, ohmic contact is conducted. In order to receive a frequency of 350 GHz, in this example, a contact area of the Al metal 501 and the n type region 511 is designed to 0.8 μm². For that reason, for example, the contact area is ensured by using a ring-shaped insulating film 514 having an inner diameter of 1 μm. The element resistance is about 1,000Ω. In this case, a power transmission efficiency from a receive antenna to the schottky barrier diode elements is about 40%.

In the above-mentioned structure, the n well 511 and the n⁺ well 512 are first formed on the Fz-Si substrate by using ion implantation. Further, after a contact hole has been formed in the insulating film 514, the Al metal films 501 and 502 are formed. Then, the BCB 513 is applied thereon, and holes that are bases of the vias 505 and 506 are formed through dry etching. Thereafter, those holes are filled through metal CVD and metal sputtering using tungsten. Subsequently, the Al metal film 504 is formed, and passivasion is conducted by the SiO₂ 515. Finally, the Al metal film 503 is formed, thus completing the structure of this example. In this way, the folded dipole antenna that can be fabricated through the semiconductor process technology is excellent as a planar antenna that can reduce impedance mismatch of the schottky barrier diode elements.

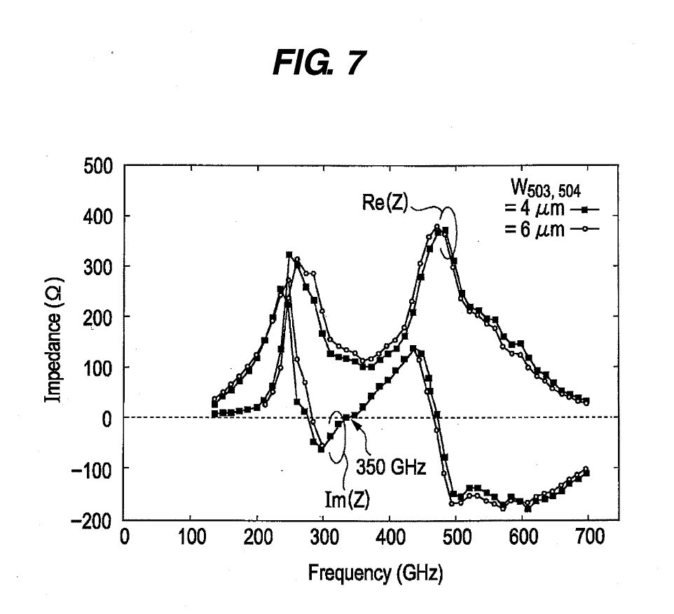

FIG. 7 shows the impedance of an antenna according to a modified example of this example. When a width W of the elements 503 and 504 in this example is changed, the calculated impedance is 120Ω in the case of W=4 μm whereas the calculated impedance is 140Ω in the case of W=6 μm. Thus, the impedance mismatch can be further reduced.

### Example 2

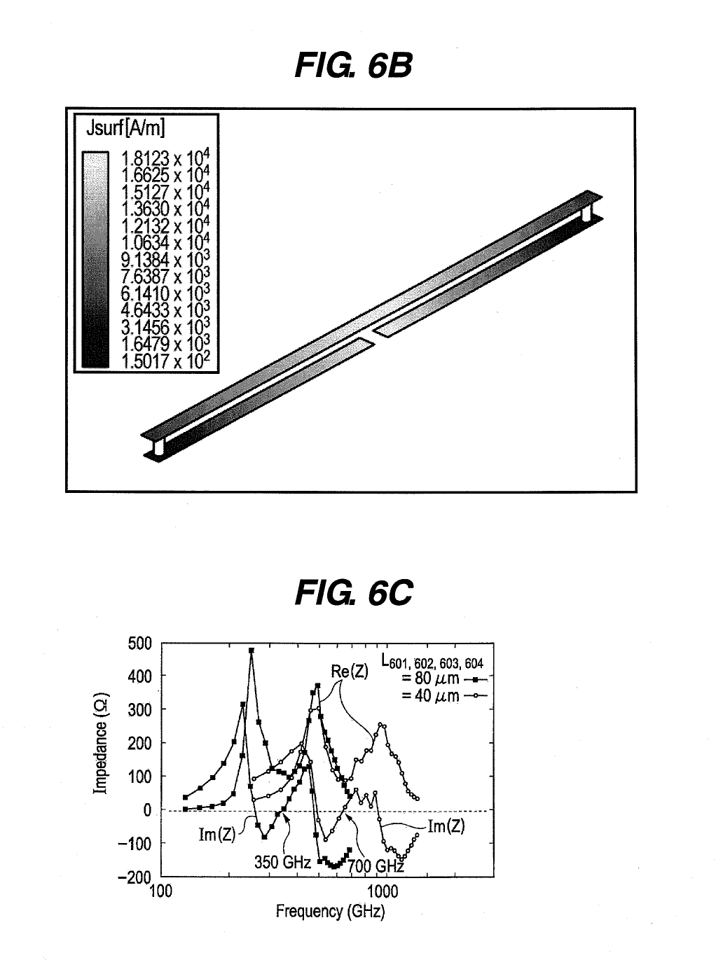

A detection element according to Example 2 is described with reference to FIGS. 6A to 6C. FIG. 6A is a cross-sectional view illustrating the detection element according to this example, FIG. 6B is a bird's-eye view illustrating an analysis model used for total electromagnetic field simulation, and FIG. 6C is a graph showing a frequency dependency of the impedance.

The detection element according to this example is also formed on an Fz-Si substrate 61. Referring to FIG. 6A, antenna elements 601, 602, 603, and 604 are made of Al metal which is the same as in Example 1. In this example, an electromagnetic wave detection element that receives frequencies of 350 GHz and 700 GHz is exemplified, and respective lengths L of the elements 601, 602, 603, and 604 are designed to 80 μm and 40 μm. The elements 603 and 604 that have been subjected to DC cut are located in a layer immediately above the elements 601 and 602. Those elements are spaced from each other by 5 μm in the thickness direction, and as in Example 1, a dielectric material 613 is made of low-loss benzocyclobutene (BCB). The element 603 (604) is connected to the element 601 (602) through a via 605 (606). In FIG. 6B, a positional relationship of those elements can be visually understood. In this example, the DC cut and the AC short-circuit are realized by putting another metal film element 607 immediately above the elements 603 and 604 insulated by a protective film 615. In this example, a length of the element 607 is 2×L which is a length of resonance.

In the above-mentioned respective antenna elements of the folded dipole antenna according to this example, FIG. 6B shows a surface current distribution of the received electromagnetic wave. Similarly to Example 1, a larger portion of the surface current distribution is around the center, and the distribution is smaller at the portions of the vias 605 and 606. Further, FIG. 6C shows the impedance of the folded dipole antenna according to this example. According to the total electromagnetic field simulation, the impedance of the antenna becomes about 120Ω and 100Ω in the vicinity of the resonance point (350 GHz and 700 GHz) of the antenna of L=80 μm and 40 μm, respectively. It is understood that the resonance frequency is inversely proportional to the length of the antenna, but the tendency of the frequency dependency of the impedance does not basically depend on the length of the antenna. For that reason, in order to receive a higher frequency, L needs to be further reduced. Schottky barrier diodes 601, 611, 612, and 602 are the same as those in Example 1. Needless to say, in order to receive a higher frequency, the contact area needs to be made smaller than that in Example 1, and the cutoff frequency f_{c} needs to be designed to be higher than the resonance frequency of the antenna. The contact area can be reduced by decreasing the inner diameter of a ring-shaped insulating film 614.

In the above embodiments and examples, the material of the semiconductor substrate is not limited to Si using an Fz (floating zone) method. The material may be Si using a Cz (Czochralski) method, which has a relatively high specific resistance of 10 Ωcm or higher. A relatively inexpensive Cz-Si is effective in the case of 1 THz or higher where free-electron absorption is small. Further, the material is not limited to Si, but semi-insulating GaAs or semi-insulating InP having a higher cutoff frequency may be used if the same dimensions are applied. Further, the metal film material is not also limited to the Al metal. Ti, Pd, Pt, Ni, Cr, or Au metal may be used, or another material (metal, semimetal, etc.) for barrier adjustment may be sandwiched between the metal film (601, etc.) and the semiconductor (611, etc.). Further, in the above embodiments and examples, the length of the dipole antenna is not limited to λ/2. For example, the dipole antenna can be deformed into a loop antenna by heightening the vias. In this case, a sum of the lengths of the four elements and the heights of the two vias, which constitute the antenna, should be designed to be equal to λ.

Further, an image forming apparatus can be provided which includes an image forming portion in which the detection elements according to the present invention are arranged in an array, and an image of an electric field distribution is formed based on an electric field of the electromagnetic wave to be detected which are detected by the multiple detection elements. In this case, the image forming apparatus supporting different frequencies can be constituted by arranging the detection elements of the present invention having different antenna lengths. Further, an image forming apparatus supporting different polarized waves can be provided by arranging the detection elements of the present invention including antennas of different directions.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2010-091682, filed Apr. 12, 2010, which is hereby incorporated by reference herein in its entirety.

What is claimed is:

1. A detection element for detecting an electromagnetic wave, comprising:
a substrate;
a schottky barrier diode disposed on the substrate; and
an antenna disposed on the substrate,
wherein the antenna includes a first conductive element and a second conductive element which are divided, a third conductive element and a fourth conductive element which are divided, a first connecting member that electrically connects the first conductive element and the third conductive element, and a second connecting member that electrically connects the second conductive element and the fourth conductive element,
wherein the first conductive element and the second conductive element, and the third conductive element and the fourth conductive element are formed on multiple surfaces of the substrate, which are spaced apart from each other along an incident direction of the electromagnetic wave, respectively, and
wherein the schottky barrier diode is electrically connected between the first conductive element and the second conductive element.

2. The detection element according to claim 1, wherein the first conductive element and the second conductive element, and the third conductive element and the fourth conductive element are spaced apart from each other through a dielectric layer along the incident direction of the electromagnetic wave, respectively.

3. The detection element according to claim 1, wherein the first conductive element and the second conductive element constitute a dipole antenna.

4. The detection element according to claim 3, wherein the first conductive element and the second conductive element has a length of ¼ of a wavelength of the electromagnetic wave along a resonance direction of the electromagnetic wave, respectively, to constitute the dipole antenna.

5. The detection element according to claim 3, wherein the first conductive element and the second conductive element has a length in a range of ⅛ or longer and ⅜ or shorter of a wavelength of the electromagnetic wave along a resonance direction of the electromagnetic wave, respectively, to constitute the dipole antenna.

6. The detection element according to claim 1, further comprising a fifth conductive element which is disposed on a surface opposite to the surface of the substrate on which the antenna is disposed.

7. The detection element according to claim 1, further comprising a first stub and a second stub which are electrically connected to the first conductive element and the second conductive element, respectively,
wherein the first stub and the second stub are capacitively coupled.

8. An image forming apparatus, comprising a plurality of the detection elements according to claim 1, which are arranged in array,
wherein an image of an electric field distribution is formed based on a detection result of the plurality of the detection elements.
